(19) United States
(12) Patent Application Publication
(10) Pub. No.: US 2013/0270677 A1
(43) Pub. Date: Oct. 17, 2013

(54) SEMICONDUCTOR DEVICE AND METHOD OF MANUFACTURING THE SAME

(71) Applicant: Elpida Memory, Inc., Tokyo (JP)

(72) Inventors: Tsuyoshi Tomoyama, Tokyo (JP); Keisuke Otsuka, Tokyo (JP)

(73) Assignee: Elpida Memory, Inc., Tokyo (JP)

(21) Appl. No.: 13/914,572

(22) Filed: Jun. 10, 2013

Related U.S. Application Data
(63) Continuation of application No. 12/662,189, filed on Apr. 5, 2010.

(30) Foreign Application Priority Data
Apr. 8, 2009 (JP) 2009-093849

(51) Int. Cl. H01L 49/02

(52) U.S. Cl. CPC H01L 28/40
USPC 257/534

(57) ABSTRACT

A semiconductor device includes a semiconductor substrate having a principal surface, a first conductor formed on the semiconductor substrate and including a conductive film having a first side wall portion and a first bottom surface portion both of which are continuously formed on a first trench having a first width in a direction parallel to the principal surface, and a second conductor formed on the semiconductor substrate and including a conductive film having a second side wall portion and a second bottom surface portion both of which are continuously formed on a second trench having a second width in a direction parallel to the principal surface, the second width being larger than the first width.

### REFERENCE TO RELATED APPLICATION

This Application is a Continuation Application of U.S. patent application Ser. No. 12/662,189, which was filed on Apr. 5, 2010, and the disclosure of which is incorporated herein in its entirety by reference thereto.

This application is based upon and claims the benefit of priority from Japanese patent application No. 2009-93849, filed on Apr. 8, 2009, the disclosure of which is incorporated herein in its entirety by reference.

### BACKGROUND OF THE INVENTION

1. Field of the Invention

An exemplary aspect of the invention relates to a semiconductor device and a method of manufacturing the same, and in particular, to a semiconductor device in which an electrode with a three-dimensional structure is formed, and a method of manufacturing the same.

2. Description of the Related Art

In DRAMs, disadvantageously, the area occupied by memory cell capacitors is reduced in connection with a reduction in chip size, and the capacitance value of each capacitor thus decreases, degrading the charge holding property of the DRAM. To avoid this problem, a structure has been developed in which the capacitor has a three-dimensional structure and thus an increased surface area. An example of such a capacitor with a three-dimensional structure is a cylinder capacitor structure (for example, Japanese Patent Application Laid-Open Nos. 2003-142605 A and 2005-229097 A).

However, in the manufacture of such cylinder capacitors, foreign matter may disadvantageously disperse in a wafer and re-adhere to the wafer, thus reducing manufacturing yield. The cause of these problems will be described with reference to FIGS. 11A to 11G. FIGS. 11A to 11G are vertical sectional views showing the structure of memory cells during respective manufacturing steps and taken across LX13a-LX13b in FIG. 10. Furthermore, along line Z1-Z2, regions close to the memory cell and the region between peripheral regions are omitted.

### <Step of Forming a Structure Shown in FIG. 11A>

Memory cell capacitors 161, guard ring 162, and lithography mark 163 are formed: guard ring 162 surrounds an array of memory cell capacitors, and lithography mark 163 is formed around the outer periphery of a chip. A region in which the memory cell capacitors are formed is hereinafter referred to as memory cell region 165. A region around the memory cell region is hereinafter referred to as peripheral region 166.

Wells, isolation regions, transistors, bit lines, cell contact plugs, and bit line contacts are formed on a semiconductor substrate by a normal DRAM forming method. Then, on-bit-line interlayer film 140 and capacitor contact plugs 141 are formed on the semiconductor substrate. On-bit-line interlayer film 140 is formed using, for example, a silicon oxide film. Capacitor contact plugs 141 are formed using, for example, a phosphorous doped polysilicon film. Stopper insulating film 142 is formed. Stopper insulating film 142 is formed of a nitride film and has a film thickness of 100 nm.

Capacitor interlayer film 150 is deposited to allow capacitors to be formed. Capacitor interlayer film 150 is formed of a silicon oxide film and has a film thickness of 1 to 3 μm. Capacitor beam insulating film 151 is formed. Capacitor beam insulating film 151 is formed of a nitride film and has a film thickness of, for example, 100 nm.

The hole portions of memory cell capacitors 161 are formed so as to expose the tops of the capacitor contact plugs. When the hole portions are formed, the hole portions of guard ring 162 and lithography mark 163 are simultaneously formed. The sizes of the hole portions are such that memory cell capacitor 161 has an opening width of 100 nm, guard ring 162 has an opening width of 300 nm, and lithography mark 163 has an opening width of 500 nm. Here, the opening width of the hole portion refers to the diameter of the largest inscribed circle drawn so as to contact the edge of the opening. For example, in the memory cell capacitor, shaped like an ellipse with a minor axis and a major axis, the opening width corresponds to the width of the largest portion of the minor axis. That is, the opening width means the film thickness in the lateral direction which is required to block the hole portion as viewed from above when a film is deposited in the hole portion.

Storage electrode conductive film 155 is formed so as to cover the side surface and bottom surface of the hole portion of memory cell capacitor 161 and the top surface of capacitor interlayer film 150. Storage electrode conductive film 155 is formed of, for example, a TiN film and has a film thickness of 30 nm.

### <Step of Forming a Structure Shown in FIG. 11B>

Mask insulating film 157 is grown and buried in the hole portions of memory cell capacitors 161. Mask insulating film 157 is formed of, for example, a silicon oxide film and has a film thickness of 70 nm. Mask insulating film 157 is formed in order to prevent storage electrode conductive film 155 formed at the bottom of the hole portion from being etched to hinder the electric connection between storage electrode conductive film 155 and the underlying contact when storage electrode conductive film 155 on the capacitor oxide film is etched, and in order to flatten differences in level formed by the capacitor holes in the surface of the memory cell array to facilitate formation of patterns during a subsequent lithography step in which capacitor beams are formed.

### <Step of Forming a Structure Shown in FIG. 11C>

Mask insulating film 157 on capacitor interlayer film 150 is etched away to expose storage electrode conductive film 155. Mask insulating film 157 is buried in the hole portions of memory cell capacitors 161.

### <Step of Forming a Structure Shown in FIG. 11D>

Storage electrode conductive film 155 on capacitor interlayer film 150 is removed by dry etching so as to remain only on the side surface and bottom surface of each of the hole portions of memory cell capacitors 161. Furthermore, storage electrode conductive film 155 in the adjacent memory cell capacitors is electrically separated into pieces for the respective memory cell capacitors. A dry etching technique is used as a method of removing storage electrode conductive film 155 formed on the capacitor interlayer film.

### <Step of Forming a Structure Shown in FIG. 11E>

Increasing miniaturization increases the aspect ratio of the capacitor. This disadvantageously reduces the mechanical strength of the capacitor, causing the capacitor to fall down during a wet treatment step such as a washing step. To avoid this problem, a beam formed of a nitride film or the like is used to couple close capacitors together so that the capacitors support each other. This prevents the capacitors from falling down.

Antireflection film 171 and photo resist film 172 are formed. A resist mask forming a support is formed using a photo lithography technique. Antireflection film 171 and capacitor beam insulating film 151 are sequentially etched by dry etching with a resist as a mask.

### <Step of Forming a Structure Shown in FIG. 11F>

Antireflection film 171 and photo resist film 172 are removed.

### <Step of Forming a Structure Shown in FIG. 11G>

Capacitor beam insulating film 151, which is formed of a silicon nitride film or the like, and storage electrode conductive film 155, which is formed of a TiN film or the like, are etched using a hydrofluoric acid liquid with a low etching rate. Capacitor interlayer film 150, which is a silicon oxide film, is etched using a hydrofluoric acid liquid with a high etching rate. Thus, capacitor interlayer film 150 is etched, with capacitor beam insulating film 151 and storage electrode conductive film 155 left. This step allows the outer peripheral wall of storage electrode conductive film 155 to be exposed. As a result, a cylinder capacitor is formed in which both an inner wall and an outer wall are accessible.

However, the present inventors have found that in the above-described method of manufacturing a capacitor, a step of etching the capacitor oxide film with a hydrofluoric acid liquid as shown in FIG. 11G may disadvantageously involve foreign matter. The foreign manner results from etching, with the hydrofluoric acid liquid, of the interlayer film formed under on-bit-line interlayer film 140 formed at the bottom of lithography mark 163 and guard ring 162, thus causing storage electrode conductive film 155 to be peeled off. The foreign matter also results from peel-off of bit lines and transistor elements formed under on-bit-line interlayer film 140. The peeled-off foreign matter may disperse in the wafer and re-adhere to the wafer. This may disadvantageously cause, for example, short-circuiting of the cylinder electrodes or improper patterning of wires resulting from the differences in level created on the interlayer film formed on the capacitors. Furthermore, capacitor interlayer film 150 covered with storage electrode conductive film 155 and the interlayer film formed under on-bit-line interlayer film 140 are etched using a hydrofluoric acid liquid to form a cavity. Thus, the bit lines and gate electrodes formed under the interlayer film are exposed. Then, a capacitive insulating film and a plate electrode are formed on the bit lines and the gate electrodes. A capacitive film formed in the cavity is unreliable and may disadvantageously cause short-circuiting between the plate electrode and the bit line or gate electrode. These factors contribute to reducing the yield of products.

Increasing integration degree reduces the margin of the matching between a pattern of the capacitors and lithography steps preceding and succeeding the formation of the pattern. Thus, increasing the accuracy of alignment has been more and more important. In response to this requirement, marks required checking patterns for overlapping misalignment and exposure alignment marks have been formed. As these lithography marks, patterns of width of 200 nm to 2 μm are used because of the need to optically recognize the marks.

Furthermore, in wet etching designed to expose the outer wall of the capacitor, the storage electrode conductive film is used to form guard ring 162 in order to limit the etching to a predetermined part of the memory cell region. Guard ring 162 is formed in order to prevent wet etching from progressing to the peripheral region formed outside the memory cell region during a step shown in FIG. 11G in which the etching is performed using hydrofluoric acid. When the cylinder interlayer film formed outside the memory cell region is etched, significant differences in level are formed in a height direction. This disadvantageously makes patterning of the plate electrode and flattening of the on-plate interlayer film difficult. A guard ring pattern is formed of a line pattern surrounding the memory cell array. A larger quantity of light impinges on the linear pattern than on dot patterns during a formation step based on exposure in a lithography step, and the linear pattern is formed to be wider than the dot pattern. Furthermore, if the guard ring pattern is even partly disconnected, the chip may become defective to the degree that the chip cannot be rescued by redundant replacement. Thus, in order to prevent improper openings from being formed, the pattern needs to be wider. As a result, the pattern is formed to have a width of about 300 nm.

Lithography mark 163 and guard ring 162 have large opening widths compared to that of the memory cell capacitor. Hence, in a dry etching step in which the conductive film is left only on the side wall and bottom of each hole portion shown in FIG. 11D, the conductive film formed at the bottom of the hole is etched away. The side wall of the storage electrode conductive film formed on lithography mark 163 and guard ring 162 do not originally serve as an element such as a memory cell capacitor but acts secondarily. Thus, storage electrodes need not be electrically connected to contact plugs. Consequently, the conductive film formed at the bottom of the hole portion is not made to be prevented from being etched away. However, in a wet etching step shown in FIG. 11G, the hydrofluoric acid liquid may seep to the bottom of the hole portion to etch the interlayer film. Moreover, the conductive film may be lifted off and act as foreign matter, resulting in defects.

An exemplary aspect of the invention provides a novel semiconductor device and a method of manufacturing the semiconductor device both of which allow the above-described problems to be solved.

### SUMMARY OF THE INVENTION

An exemplary aspect of the invention provides a method of manufacturing a semiconductor device, the method comprising:
forming an interlayer film on a semiconductor substrate having a principal surface;
forming a first trench having a first opening width and a second trench having a second opening width larger than the first opening width in the interlayer film;
forming a conductive film on a top surface of the interlayer film and on a side surface and a bottom surface of each of the first trench and the second trench; and
etching the conductive film to remove the conductive film formed on the top surface of the interlayer film, while leaving the conductive film formed on the side surface and the bottom surface of each of the first trench and the second trench, thus forming a first conductor including a conductive film which is continuous over the side surface and the bottom surface of the first trench and a second conductor including a conductive film which is continuous over the side surface and the bottom surface of the second trench.

An exemplary aspect of the invention provides a semiconductor device comprising:
a semiconductor substrate having a principal surface;
a first conductor formed on the semiconductor substrate and including a conductive film having a first side wall portion and a first bottom surface portion both of which are continuously formed on a first trench having a first width in a direction parallel to the principal surface; and
a second conductor formed on the semiconductor substrate and including a conductive film having a second side wall portion and a second bottom surface portion both of which are continuously formed on a second trench having a second width in a direction parallel to the principal surface, the second width being larger than the first width.

In an exemplary aspect of the invention, in a semiconductor device including a capacitor with a small opening width and a capacitor with a large opening width, each of the capacitors is formed such that the bottom of a lower electrode is left in the resultant capacitor. This allows the capacitor portion to be prevented from acting as foreign matter during a manufacturing process. Thus, an exemplary aspect of the invention can provide a reliable semiconductor device including a capacitor with a small opening width and a capacitor with a large opening width and offering a high yield.

### BRIEF DESCRIPTION OF THE DRAWINGS

FIG. 1A is a vertical sectional view showing a structure of a memory cell in a semiconductor device according to a first embodiment;

FIG. 1B is a planar sectional view showing a structure of a memory cell in a semiconductor device according to a first embodiment, which is taken across line LZ13a-LZ13b in FIG. 1A;

FIG. 1C is a planar sectional view showing a structure of a memory cell in a semiconductor device according to a first embodiment, which is taken across line LZ13c-LZ13d in FIG. 1A;

FIG. 2 is a conceptual drawing showing a structure of a semiconductor device according to a first embodiment, wherein FIG. 2(a) is a diagram showing an appearance of a semiconductor device as a whole, FIG. 2(b) is an enlarged view of a memory cell array, FIG. 2(c) is an enlarged view of a pattern of memory cell capacitors, and FIG. 2(d) is an enlarged view of a lithography mark portion;

FIGS. 3A to 3K are vertical sectional views showing a structure of memory cells during respective manufacturing steps of a method of manufacturing a semiconductor device according to a first embodiment, which are taken across line LX13a-LX13b in FIG. 10;

FIGS. 3L and 3M are vertical sectional views showing a structure of a memory cell during steps in FIGS. 3E and 3K, respectively, which are taken across line LY13a-LY13b in FIG. 10;

FIGS. 4A and 4B are vertical sectional views showing a structure of memory cells during respective manufacturing steps of a method of manufacturing a semiconductor device according to a second embodiment, which are taken across line LX13a-LX13b in FIG. 10;

FIGS. 5A and 5B are vertical sectional views showing a structure of memory cells during respective manufacturing steps of a method of manufacturing a semiconductor device according to a third embodiment, which are taken across line LX13a-LX13b in FIG. 10;

FIGS. 6A to 6F are vertical sectional views showing a structure of memory cells during respective manufacturing steps of a method of manufacturing a semiconductor device according to a fourth embodiment, which are taken across line LX13a-LX13b in FIG. 10;

FIGS. 7A to 7F are vertical sectional views showing a structure of memory cells during respective manufacturing steps of a method of manufacturing a semiconductor device according to a fifth embodiment, which are taken across line LX13a-LX13b in FIG. 10;

FIGS. 8A and 8B are vertical sectional views showing a structure of memory cells during respective manufacturing steps of a method of manufacturing a semiconductor device according to a sixth embodiment, which are taken across line LX13a-LX13b in FIG. 10;

FIG. 9A is a vertical sectional view showing a structure of memory cells during a manufacturing step of a method of manufacturing a semiconductor device according to a seventh embodiment, which is taken across line LX13a-LX13b in FIG. 10;

FIG. 9B is a vertical sectional view showing a structure of a semiconductor device according to a seventh embodiment, which corresponds to FIG. 1A;

FIGS. 10A to 10C are vertical sectional views showing a structure of memory cells during respective manufacturing steps of a method of manufacturing a semiconductor device according to an eighth embodiment, which are taken across line LX13a-LX13b in FIG. 10; and

FIGS. 11A to 11G are vertical sectional views showing a structure of memory cells during respective manufacturing steps of a method of manufacturing a semiconductor device according to a related art of an exemplary embodiment, which are taken across line LX13a-LX13b in FIG. 1C.

### DETAILED DESCRIPTION OF THE PREFERRED EMBODIMENTS

An exemplary embodiment will be described below with reference to the drawings.

### First Embodiment

### <<Structure>>

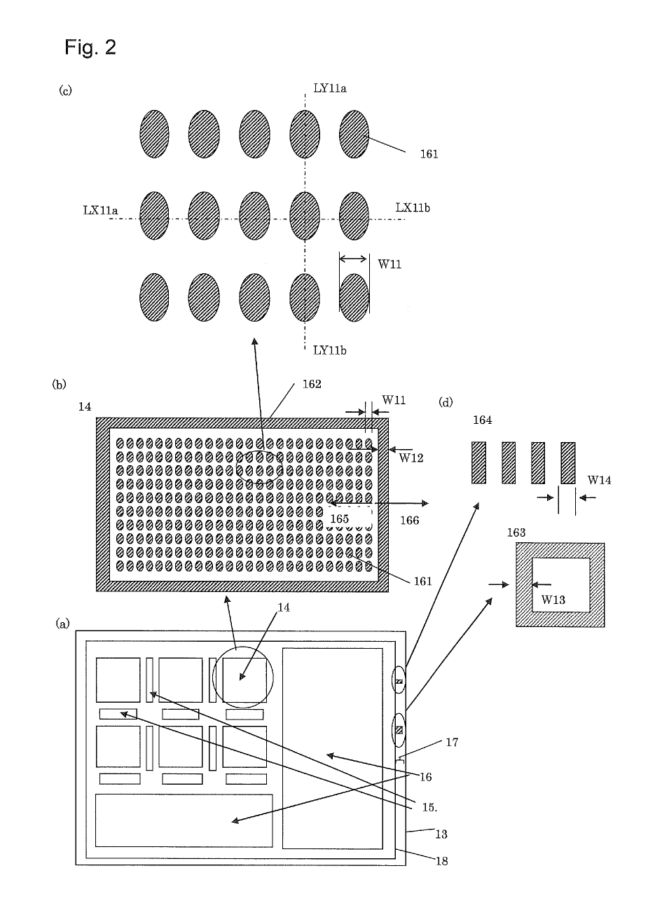

FIG. 2 is a conceptual drawing showing a structure of a semiconductor device according to a first embodiment, wherein FIG. 2(a) is a diagram showing an appearance of a semiconductor device as a whole, FIG. 2(b) is an enlarged view of a memory cell array, FIG. 2(c) is an enlarged view of a pattern of memory cell capacitors, and FIG. 2(d) is an enlarged view of a lithography mark portion.

As shown in FIG. 2(a), scribe line 17 encloses the periphery of semiconductor chip 13 and element region 18 is formed inside scribe line 17. Memory cell arrays 14, array circuits 15, and peripheral circuit 16 are formed in element region 18; each of memory cell arrays 14 includes memory cells arranged therein in array form, and array circuits 15 configured to drive memory cell arrays 14. On the other hand, lithography marks such as lithography marks 163 and second lithography marks 164 are formed on scribe line 17. Although, in a first embodiment, the lithography marks are formed in the scribe region, the lithography marks may be formed in a chip.

As shown in FIG. 2(b), memory cell capacitors 161 of dot-like memory cells are formed in memory cell array 14 in array form. A pattern of memory cell capacitors 161 is as shown in FIG. 2(C). Furthermore, guard ring 162 is formed so as to surround the array. Guard ring 162 is used to limit oxide film etching for exposing the outer wall of a cylinder, to the memory cell array region. Although a first embodiment uses the guard ring, the formation of the guard ring may be omitted depending on the type of the product.

On the other hand, as shown in an enlarged view in FIG. 2(d), lithography mark 163 allows detection of misalignment between the capacitor pattern formed by exposure and steps preceding and succeeding the formation of the pattern. Second lithography mark 164 allows a wafer position to be detected for exposure.

A first embodiment uses a lithography technique with a minimum processing size of 100 nm. The minor axis of memory cell capacitor 161 has a width w11 of 100 nm. The guard ring pattern has a width w12 of 300 nm. Lithography mark 163 has a width w13 of 500 nm. Second lithography mark 164 has a width w14 of 500 nm. In a first embodiment, the lithography mark is a hole portion formed during capacitor steps, which has the largest width in the semiconductor chip. The opening width of the opening of the hole portion refers to the diameter of the largest inscribed circle drawn so as to contact the outer periphery of the opening of the hole portion at the top surface thereof as viewed in a plane parallel to the principal surface of the semiconductor substrate. For example, in the memory cell capacitor, shaped like an ellipse with a minor axis and a major axis, the opening width corresponds to the width of the largest portion of the minor axis. That is, the opening width means the film thickness in the lateral direction which is required to block the hole portion as viewed from above when a film is deposited in the hole portion.

In capacitor steps, besides the above-described components, a TEG such as a film thickness measurement pattern for a capacitor interlayer film may be formed. In this case, for example, a rectangular pattern that is 30 μm on a side is used.

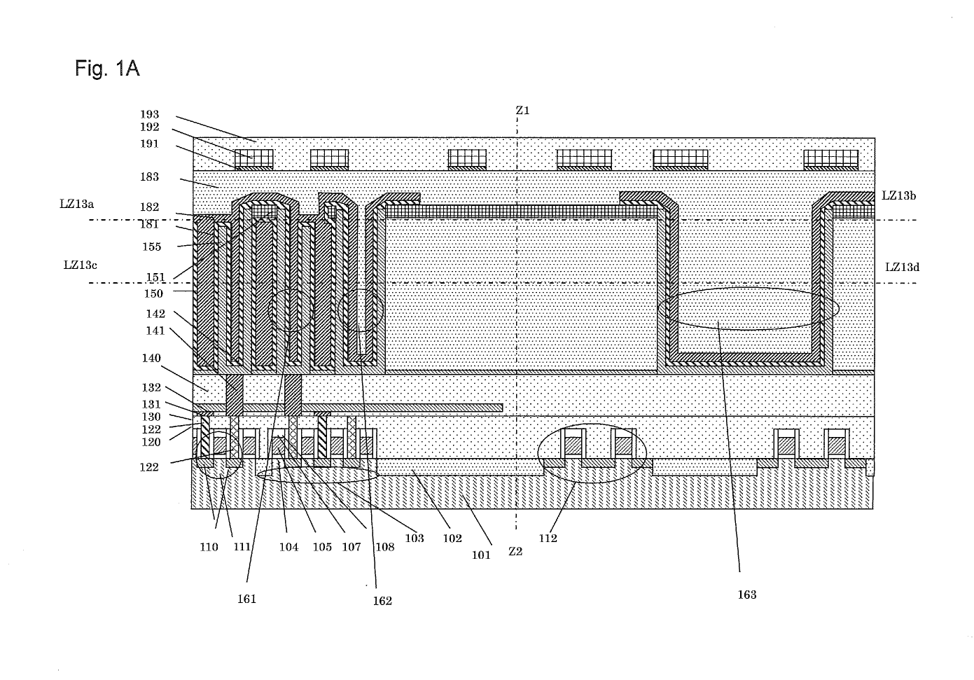

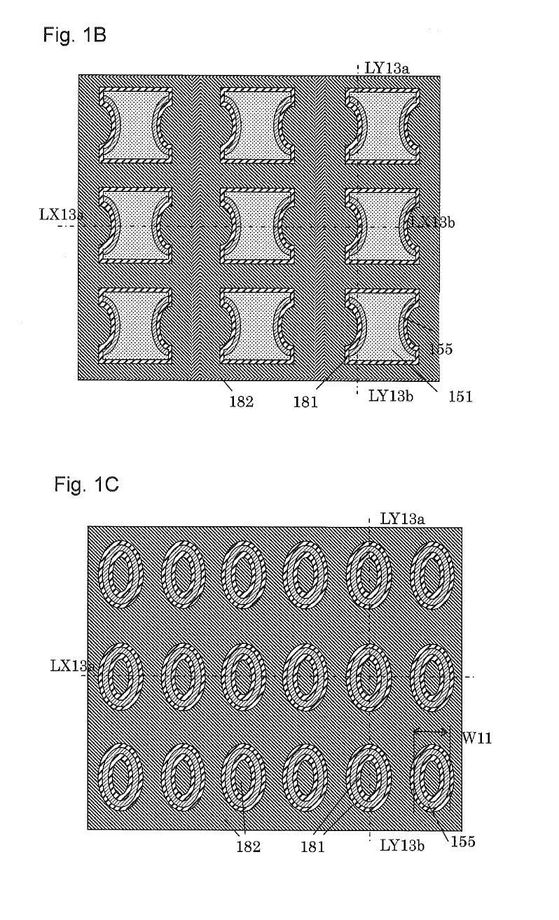

FIG. 1A is a vertical sectional view showing a structure of memory cells in a semiconductor device according to a first embodiment. FIG. 1A is a sectional view taken across line LX13a-LX13b in FIG. 1B, described below. Furthermore, along line Z1-Z2, regions close to a memory cell and a region between peripheral regions are omitted.

Reference numerals shown in FIG. 1A are as follows: 101 denotes a semiconductor substrate, 102 denotes an isolation region, 103 denotes an element formation region, 104 denotes a gate insulating film, 105 denotes a gate electrode, 107 denotes a silicon nitride film mask, 108 denotes a silicon nitride film side wall, 110 denotes a source drain diffusion region, 111 denotes a memory cell transistor, 112 denotes a peripheral transistor, 120 denotes an on-gate interlayer film, 122 denotes a cell contact plug, 130 denotes an on-cell-contact-plug interlayer film, 131 denotes a bit line contact, 132 denotes a bit line, 140 denotes an on-bit-line interlayer film, 141 denotes a capacitor contact plug, 142 denotes a stopper insulating film, 150 denotes a capacitor interlayer film, 151 denotes a capacitor beam insulating film, 155 denotes a storage electrode conductive film, 161 denotes a memory cell capacitor, 162 denotes a guard ring, 163 denotes a lithography mark, 181 denotes a capacitive insulating film, 182 denotes a plate electrode, 183 denotes an on-plate-electrode interlayer film, 191 denotes a TiN film, 192 denotes an AlCu wire, and 193 denotes an on-wire interlayer film.

FIG. 1B is a planar sectional view which is taken across line LZ13a-LZ13b in FIG. 1A. In this cross section, storage electrode conductive film 155, capacitor beam insulating film 151, capacitive insulating film 181, and plate electrode 182 are formed.

FIG. 1C is a planar sectional view which is taken across line LZ13a-LZ13b in FIG. 1A. In the cross section, storage electrode conductive film 15S, capacitive insulating film 181, and plate electrode 182 are formed.

### <<Manufacturing Method>>

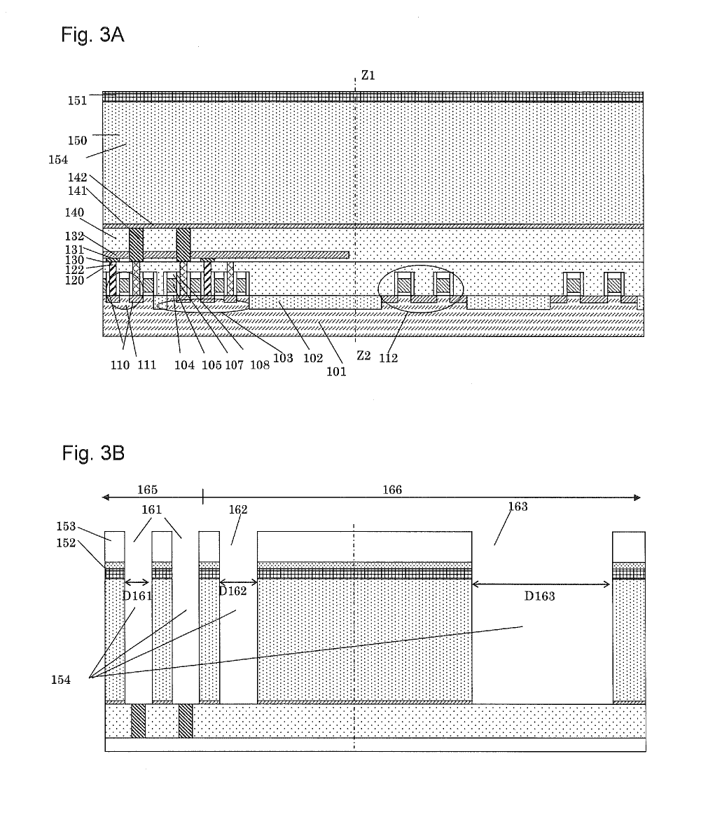

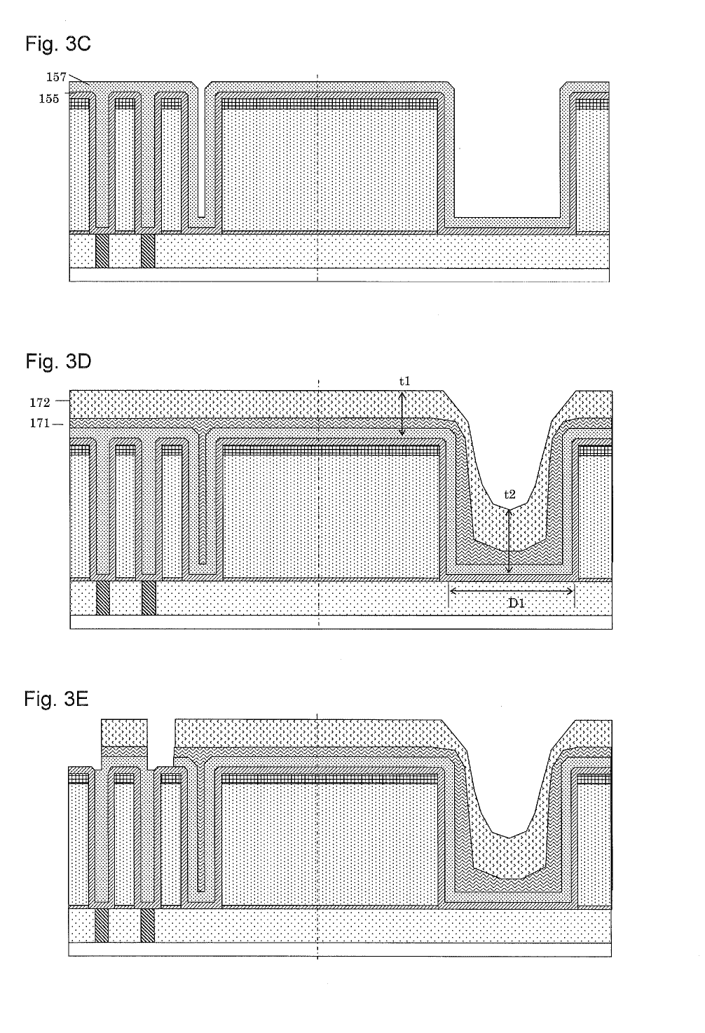

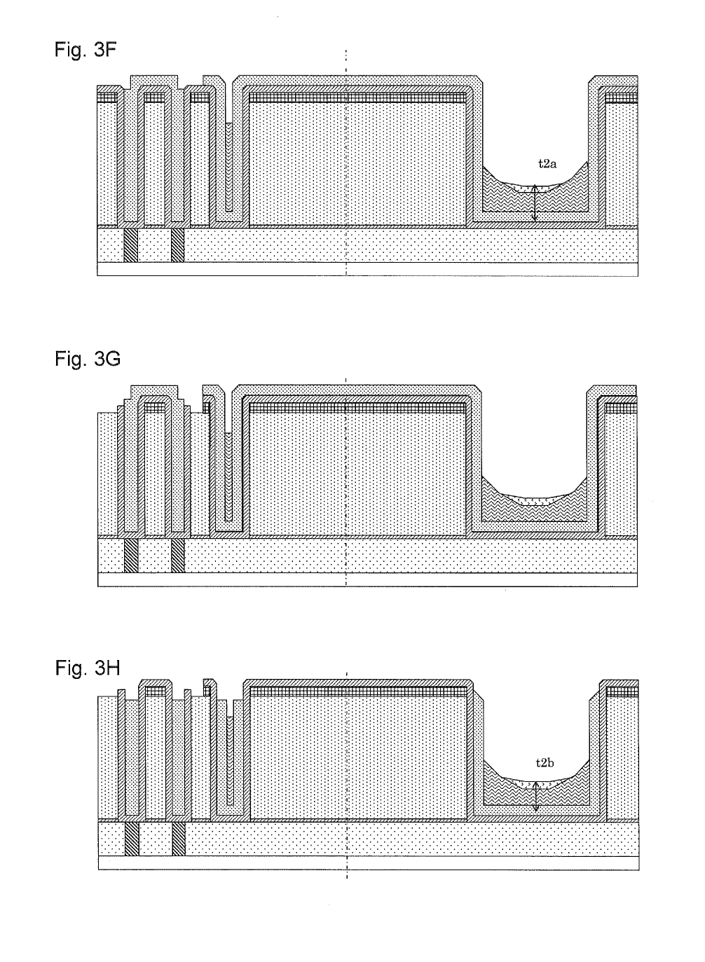

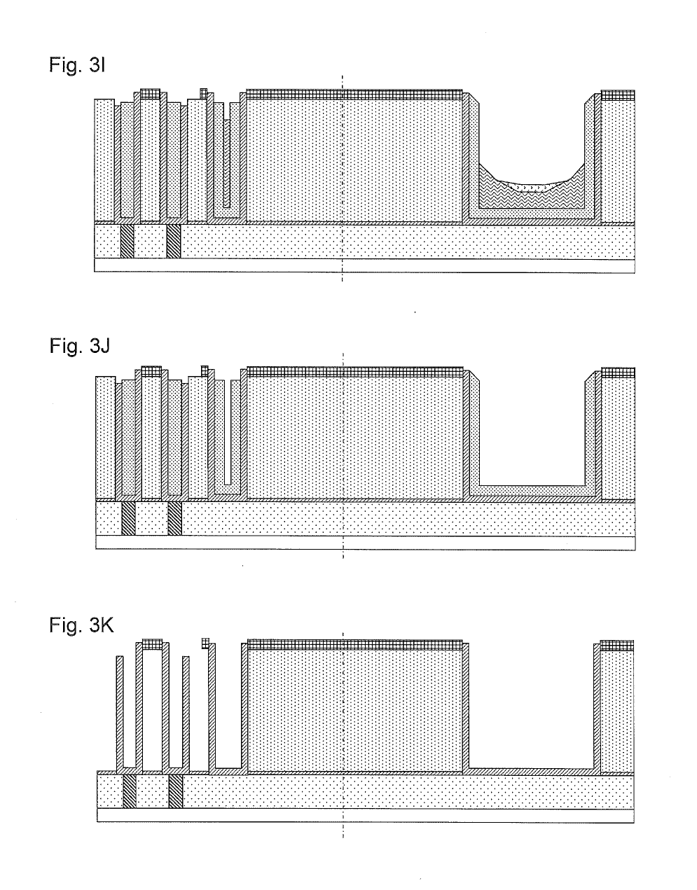

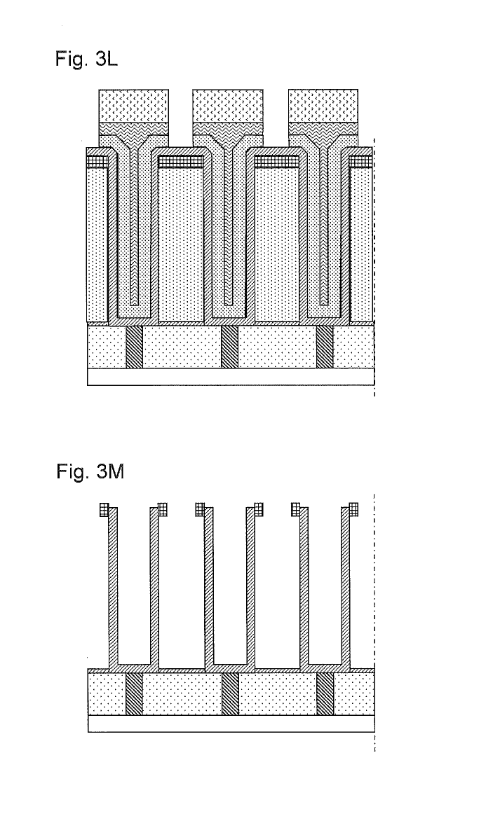

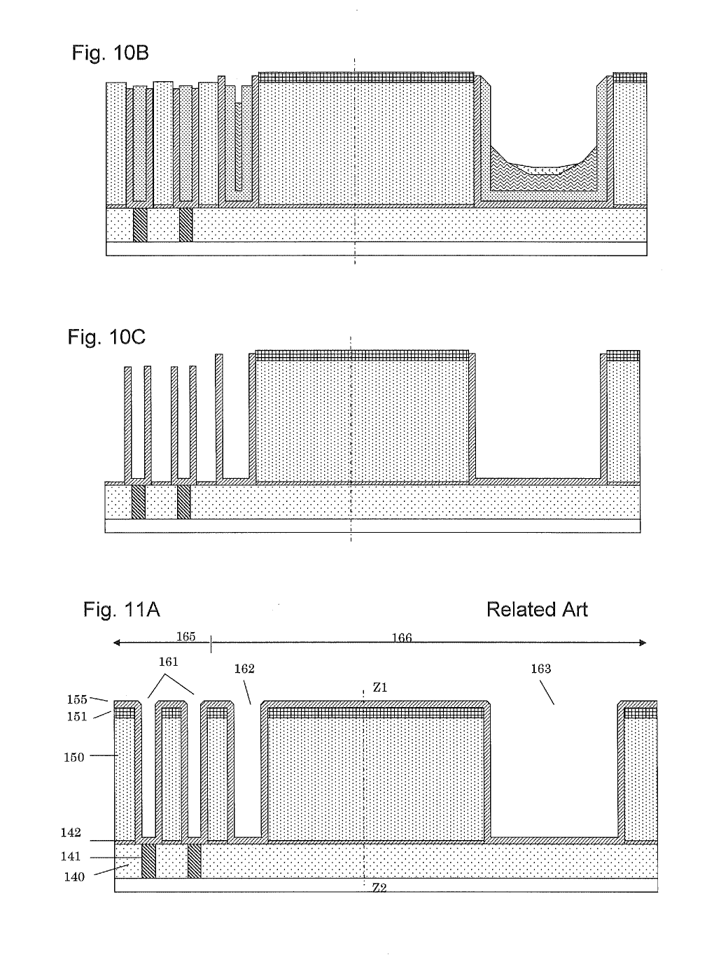

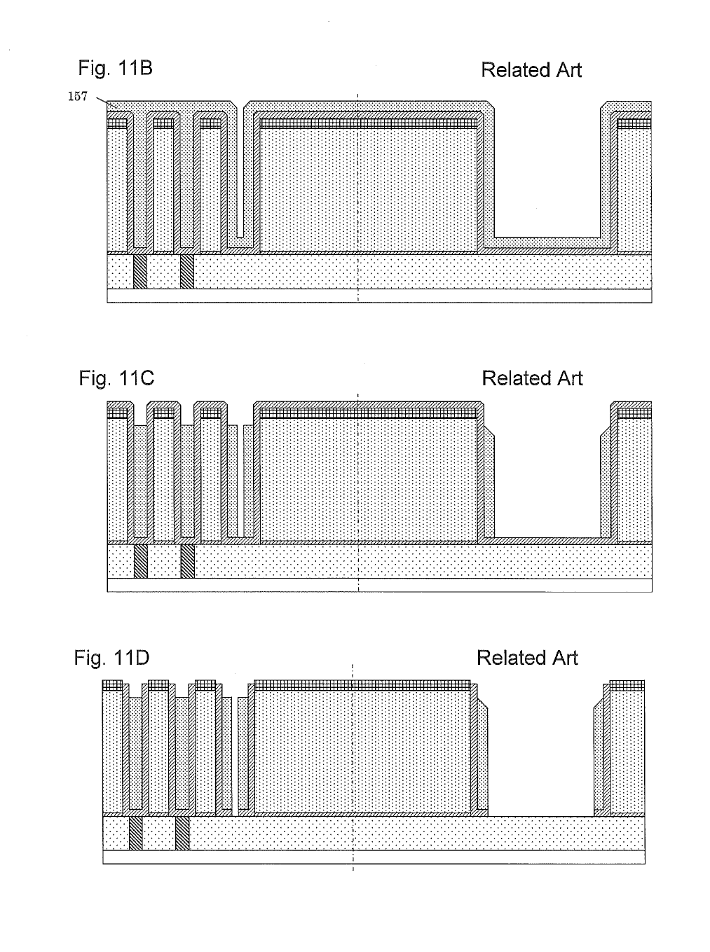

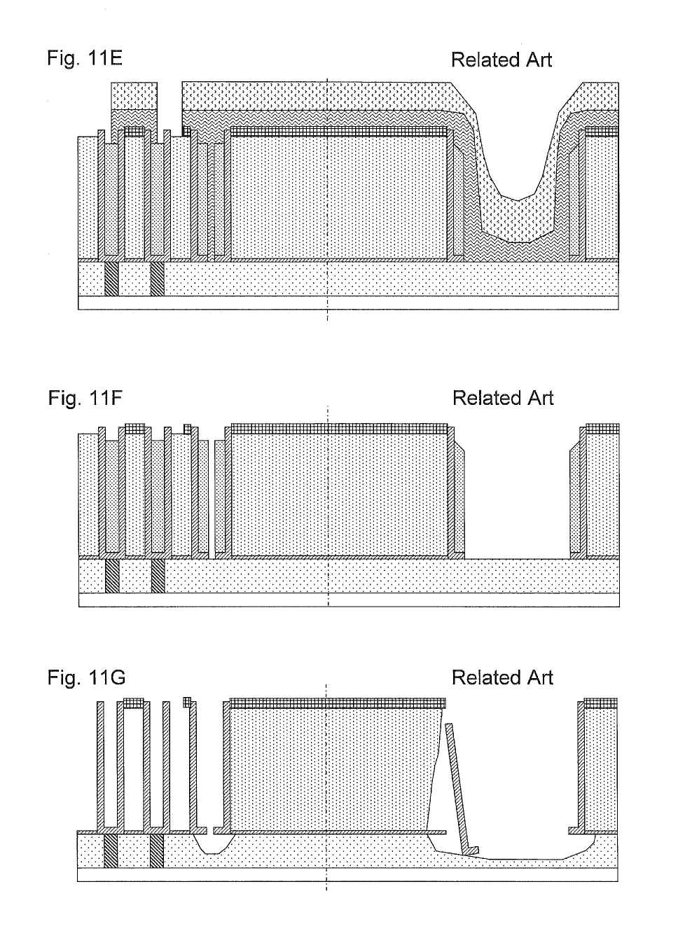

A method of manufacturing a semiconductor device according to a first embodiment will be described with reference to FIGS. 3A to 3M. FIGS. 3A to 3K are vertical sectional views showing a structure of memory cells during respective manufacturing steps, which are taken across line LX13a-13b in FIG. 10. FIGS. 3L and 3M are vertical sectional views showing a structure of a memory cell during steps in FIGS. 3E and 3K, respectively, which are taken across line LY13a-LY13b in FIG. 10. Furthermore, along line Z1-Z2, regions close to the memory cell and the region between peripheral regions are omitted.

### <Step of Forming a Structure Shown in FIG. 3A>

Isolation region 102 is formed on p-type semiconductor substrate 101. Gate insulating film 104, gate electrode 105, silicon nitride film mask 107, silicon nitride film side wall 108, and source drain diffusion layer 110 are formed on element formation region 103. Memory cell transistor 111 is formed in a memory cell portion. Peripheral transistor 112 is formed in a peripheral region.

A silicon oxide film is deposited and then flattened by a CMP method to form on-gate interlayer film 120. A cell contact hole is formed in on-gate interlayer film 120 by a lithography technique and etching technique. A phosphorous-doped polycrystalline silicon film is deposited by an LP-CVD method. A plug is then formed by a CMP method. Cell contact plugs 122 connected to source drain diffusion layer 110 are then formed.

A silicon oxide film is deposited and then flattened by a CMP method to form on-cell-contact-plug interlayer film 130. Bit line contact holes through which respective cell contact plugs 122 are exposed are formed by a lithography technique and an etching technique.

Bit line contact 131 is formed. Bit line contact 131 is formed by depositing, for example, a barrier metal film of a TiN film/Ti film as well as a tungsten film, and then burying the films by CMP. A tungsten film is deposited and then patterned using the lithography technique and a dry etching technique, to form bit lines 132.

A silicon oxide film is deposited and then flattened by the CMP method to form on-bit-line interlayer film 140. Capacitor contact holes are formed by the lithography technique and the etching technique so as to extend through on-bit-line interlayer film 140 formed between bit lines 132 to cell contact plugs 122. Thus, capacitor contact plugs 141 made of a phosphorous-doped polycrystalline silicon film are formed. Stopper insulating film 142 is formed under a storage electrode in the capacitor; stopper insulating film 142 serves as a stopper during a subsequent step, that is, a step of etching the silicon oxide film. Stopper insulating film 142 is formed of, for example, a silicon nitride film deposited by LP-CVD, and has a film thickness of 100 nm.

Capacitor interlayer film 150 is formed as an interlayer film. A silicon oxide film of film thickness of about 1,000 nm is deposited as capacitor interlayer film 150 by, for example, the LP-CVD method. As the silicon oxide film, a silicon oxide film doped with impurities such as a BPSG film, a non-doped silicon oxide film, or the like is applicable. The surface of capacitor interlayer film 150 is flattened by the CMP method.

Capacitor beam insulating film 151 as a cap insulating film is deposited. Capacitor beam insulating film 151 is formed of, for example, a silicon nitride film and has a film thickness of, for example, 100 nm.

### <Step of Forming a Structure Shown in FIG. 3B>

Antireflection film 152 and photo resist film 153 are applied. The lithography technique is used to form, on photo resist film 153, an opening pattern via which memory cell capacitors 161, guard ring 162, and lithography mark 163 are formed.

Antireflection film 152 is etched by the dry etching technique through photo resist film 153 as a mask. Subsequently, capacitor beam insulating film 151, capacitor interlayer film 150, and stopper insulating film 142 are etched through photo resist film 153 and antireflection film 152 as a mask. Thus, hole portions 154 that reach capacitor contact plugs 141 are formed. Hole portions are formed in memory cell capacitors 161, guard ring 162, and lithography mark 163.

Here, a region in which a memory cell is formed is defined as memory cell region 165. A region outside the memory cell region is defined as peripheral region 166. Memory cell capacitors 161 are formed in memory cell region 165. Guard ring 162 is formed so as to surround a memory cell array in which memory cell capacitors 161 are formed in array form. Lithography mark 163 is formed around the outer periphery of the chip.

In a first embodiment, memory cell capacitor 161 has minor axis width D161 of 100 nm. Guard ring 162 has pattern width D162 of 300 nm. Lithography mark 163 has width D163 of 500 nm. In a first embodiment, lithography mark 163 is a hole portion having the largest width among the components formed during capacitor steps.

### <Step of Forming a Structure Shown in FIG. 3C>

Storage electrode conductive film 155, as a conductive film, formed of a continuous film is deposited in the hole portions of memory cell capacitors 161, guard ring 162, and lithography mark 163 and on capacitor interlayer film 150. Conductive film 155 is formed of, for example, a single-layer TiN film of thickness of 30 nm grown by a CVD method. Alternatively, a stack film of Ti and TiN (Ti: 10 nm, TiN: 20 nm) may be used.

Mask insulating film 157 is deposited. Mask insulating film 157 is formed of, for example, a silicon oxide film grown by an LPCVD method and has a film thickness of 70 nm. Mask insulating film 157 is buried in each of memory cell capacitors 161 with a high coverage such that mask insulating film 157 extends from the hole portion to bottom of memory cell capacitor 161. The opening of memory cell capacitor 161 is blocked. Mask insulating film 157 is formed in order to prevent storage electrode conductive film 155 at the bottom of the hole portion from being etched to hinder the electric connection between storage electrode conductive film 155 and the underlying contact when storage electrode conductive film 155 on the capacitor oxide film is etched, and in order to flatten differences in level formed by the capacitor holes in the surface of the memory cell array to facilitate formation of a pattern during a subsequent lithography step in which a beam is formed.

### <Step of Forming a Structure Shown in FIG. 3D>

Antireflection film 171 and photo resist film 172 are applied. For example, antireflection film 171 has a film thickness of 100 nm, and photo resist film 172 has a film thickness of 300 nm.

Here, in thickness t equal to the sum of the film thicknesses of three layers of insulating films formed on storage electrode conductive film 155, that is, mask insulating film 157, antireflection film 171, and photo resist film 172, the thickness on the capacitor interlayer film is defined as t1, and the thickness of lithography mark 163 with a large opening diameter from the bottom thereof is defined as t2. Then, the insulating films are formed such that t2>t1. The setting of t2>t1 is realized by increasing the fluidity of the three layers of insulating films and depositing the three layers of insulating films to large thicknesses such that t1>D1 denoting the opening width of lithography mark 163.

A first embodiment needs to form a fine beam pattern with an F-number of about 100 nm. Consequently, the thickness of photo resist film 172 needs to be about 300 nm in order to avoid the resist from falling down. The limitation of the thickness of the photo resist in turn limits the thicknesses of antireflection film 171 and mask insulating film 157. Thus, in a first embodiment, increasing film thickness t of the three layers to about D1 is difficult. Hence, the three layers are formed so that film thickness t of the three layers is made as thick as possible and so that a resist film and an antireflection film both with a high fluidity are used to set t2>t1.

### <Step of Forming a Structure Shown in FIG. 3E>

The lithography technique is used to form a resist pattern required to process and form a capacitor beam. In the resist pattern, a capacitor beam formation region of the memory cell, the region outside guard ring 162, and lithography mark 163 are covered with resist.

The dry etching technique is used to etch away antireflection film 171 through photo resist film 172 as a mask. Subsequently, mask insulating film 157 is etched away using the dry etching technique.

### <Step of Forming a Structure Shown in FIG. 3F>

Dry etching is performed on photo resist film 172 and antireflection film 171 to etch away photo resist film 172 and antireflection film 171 on the capacitor interlayer film. Thus, mask insulating film 157 is exposed. Furthermore, in a first embodiment, the etching is performed such that a film thickness t2a equal to the sum of the film thicknesses of photo resist film 172 and antireflection film 171 remaining at the bottom of the hole portion of lithography mark 163 is about 100 nm or more; the bottom of the hole portion of lithography mark 163 has the largest opening width. Film thickness t2a is set so as to avoid exposing the surface of storage electrode conductive film 155 formed at the bottom of lithography mark 163 after etching of storage electrode conductive film 155, etching of capacitor beam insulating film 151, etching of mask insulating film 157, and etching of storage electrode conductive film 155 during steps of forming the structures shown in FIGS. 3G and 3H. The required film thickness is determined depending on the etching conditions. Resultant film thickness t2a can be set to 100 nm or more by controlling the overetching amount of dry etching and initial film thickness t2.

Photo resist film 172 and antireflection film 171 can be etched using, for example, the condition that etching gas contains Cl₂ and O₂. This gas-based etching allows photo resist film 172 and antireflection film 171 to be etched at almost the same rate and as the same material. Furthermore, a high etching selectivity is exhibited for the silicon oxide film, and the underlying mask insulating film is not substantially etched.

### <Step of Forming a Structure Shown in FIG. 3G>

Storage electrode conductive film 155 is etched away by dry etching through mask insulating film 157 as a mask. The etching is performed using gas containing chlorine. Subsequently, capacitor beam insulating film 151 is etched away by dry etching through mask insulating film 157 as a mask. The etching is performed using gas containing CF₄.

### <Step of Forming a Structure Shown in FIG. 3H>

Mask insulating film 157 on capacitor interlayer film 150 is etched by dry etching. The etching is performed using gas containing CF₄.

The inner bottom of lithography mark 163 is protected by photo resist film 172 and antireflection film 171. The bottom of the mask insulating film remains without being etched. The mask insulating film is formed so as to extend from the inner side surface to inner bottom surface of the hole. In a first embodiment, film thickness t2b resulting from the above-described step and which is equal to the sum of the thicknesses of photo resist film 172 and antireflection film 171 is set to about 50 nm or more at the bottom of the hole portion of lithography mark 163. To obtain this film thickness, at least the antireflection film has only to be left. Film thickness t2b serves to avoid exposing the surface of storage electrode conductive film 155 formed at the bottom of lithography mark 163 after etching of storage electrode conductive film 155 during a subsequent step of forming a structure shown in FIG. 3I. Film thickness t2b depends on the condition of the etching of storage electrode conductive film 155. Resultant film thickness t2b can be set to 50 nm or more by controlling the overetching amount of dry etching and film thicknesses t2 and t2a.

### <Step of Forming a Structure Shown in FIG. 3I>

Storage electrode conductive film 155 formed on capacitor interlayer film 150 is removed by dry etching to electrically separate the adjacent memory cell capacitors. Since the inside of lithography mark 163 is protected by photo resist film 172, antireflection film 171, and mask insulating film 157, storage electrode conductive film 155 is not etched. A first embodiment performs the etching in which storage electrode conductive film 155 formed on the memory cell capacitors is separated into pieces, with a protective film formed at the bottom of a large capacitor pattern with a large opening diameter such as lithography mark 163. This avoids etching the conductive film formed at the bottom of lithography mark 163, which is a large capacitor pattern. Furthermore, the protective film can be formed using the photo resist film and antireflection film for lithography for formation of a capacitor beam insulating film, without the need to deposit a new film. As a result, an increase in costs can be prevented.

A series of steps shown in FIGS. 3E to 3I are consecutively carried out in a dry etching apparatus sealed from outside air. This eliminates the need to use different apparatuses for the respective etching operations, thus reducing investment costs for the apparatus.

### <Step of Forming a Structure Shown in FIG. 3J>

Photo resist film 172 and antireflection film 171 remaining at the bottom of lithography mark 163 are removed by wet etching. Alternatively, photo resist film 172 and antireflection film 171 remaining at the bottom of lithography mark 163 may be removed by an ashing method using oxygen gas.

### <Step of Forming a Structure Shown in FIG. 3K>

Capacitor interlayer film 150 with the top surface thereof exposed is etched by wet etching using a hydrofluoric acid liquid. Wet etching is performed using a hydrofluoric acid liquid that exhibits a high etching selectivity for capacitor beam insulating film 151 and storage electrode conductive film 155, so as to leave capacitor beam insulating film 151 and storage electrode conductive film 155. The outer wall of storage electrode conductive film 155 is exposed. Thus, a cylinder capacitor storage electrode with the outer wall and the surface of the inner wall is formed. The etching may be performed using HF gas of gas phase.

In a first embodiment, guard ring 162 is formed around the periphery of the memory cell array. Hence, the capacitor interlayer film in the memory cell region is etched away, with the peripheral regions unetched. This prevents a possible difference in level between the memory cell and the periphery, thus preventing patterning for element formation during a subsequent step from being affected.

### <Subsequent Steps>

As shown in FIG. 1, capacitive insulating film 181 is deposited. For example, capacitive insulating film 181 is formed of Ta₂O₅ and has a film thickness of 10 nm. Plate electrode 182 is deposited on capacitive insulating film 181. For example, plate electrode 182 is formed of TiN and has a film thickness of, for example, 15 nm. Thus, a cylinder capacitor is completed.

On-plate-electrode interlayer film 183 is formed on the plate electrode. On-plate-electrode interlayer film 183 is formed of, for example, a silicon oxide film. Contact plugs are formed, and TiN film 191 and a wire including AlCu wire 192 are formed both of which are connected to the contact plugs. On-wire interlayer film 193 is formed on the wire. Thereafter, bonding pads and the like are formed to complete a DRAM.

As described above, the etching is performed in which storage electrode conductive film 155 formed on the memory cell capacitors is separated into pieces, with a protective film formed at the bottom of a large capacitor pattern with a large opening diameter such as lithography mark 163. This avoids etching the conductive film formed at the bottom of lithography mark 163, which is a large capacitor pattern. The conductive film remaining at the bottom of lithography mark 163 preferably has a thickness of 15 nm or more to prevent a locally-weak portion of the conductive film from cracking. During a step of etching capacitor interlayer film 150 in order to expose the outer wall of the storage electrode conductive film formed in the hole portion of the memory cell capacitor, the interlayer film under the bottom of lithography mark 163 which is a large capacitor pattern, is prevented from being etched. This enables generation of foreign matter to be inhibited. As a result, for example, a wide lithography mark, a guard ring pattern, and a TEG can be formed in the chip during capacitor steps. Therefore, the area of the chip can be reduced, and very reliable devices can be formed.

Moreover, the protective film, serving to protect the bottom of the large capacitor pattern, is formed using the photo resist film and the antireflection film for lithography for formation of a beam insulating film. Thus, the protective film can be formed, without the need to form a new film and increasing in costs. Moreover, storage electrode conductive film 155 formed on the memory cell capacitors is separated into pieces by means of etching. This avoids using the CMP technique, which requires relatively high manufacturing costs. In addition, a series of etching steps can be consecutively carried out in a dry etching apparatus sealed from outside air. This enables a reduction in investment costs for the apparatus.

As described above, a device with inexpensive, reliable cylinder capacitors can be provided.

### Second Embodiment

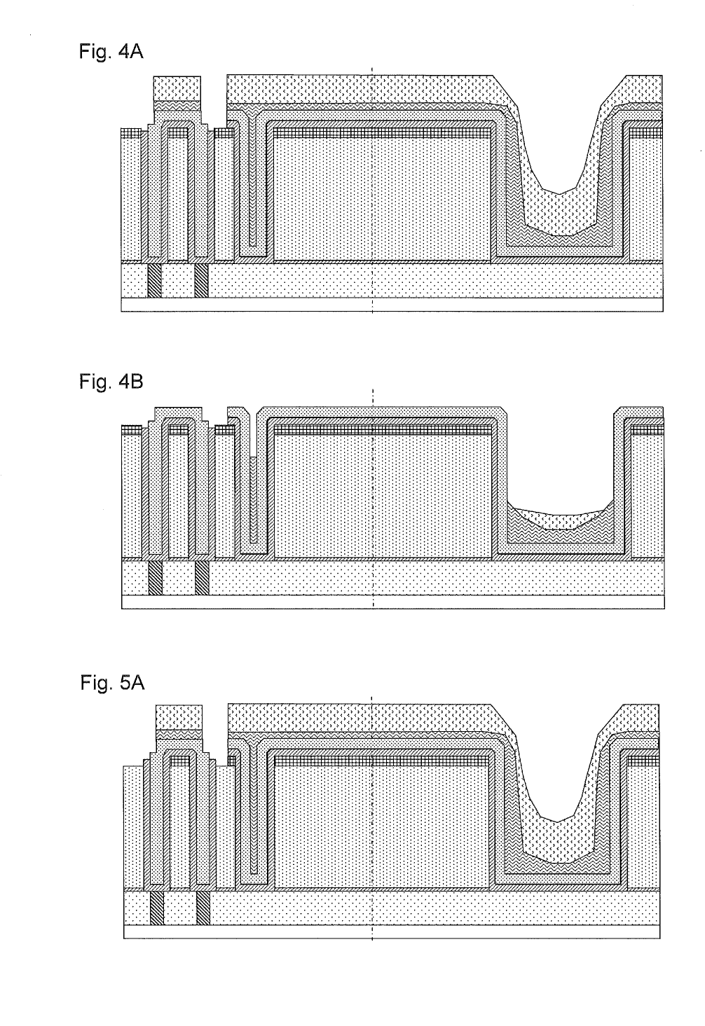

In a second embodiment, a manufacturing method according to a first embodiment is partly changed. A method of manufacturing a semiconductor device according to a second embodiment will be described with reference to FIGS. 4A and 4B. FIGS. 4A and 4B are vertical sectional views showing a structure of memory cells during respective manufacturing steps, which are taken across line LX13a-LX13b in FIG. 10.

### <Step of Forming a Structure Shown in FIG. 4A>

Steps shown in FIGS. 3A to 3E for a first embodiment are carried out. Subsequently, exposed storage electrode conductive film 155 is etched.

### <Step of Forming a Structure Shown in FIG. 4B>

A step shown in FIG. 3F for a first embodiment is carried out to leave photo resist film 172 and antireflection film 171 in a large capacitor portion.

### <Subsequent Steps>

Storage electrode conductive film 155 has already been etched away. Thus, capacitor beam insulating film 151 is etched by a step shown in FIG. 3G for a first embodiment. Thereafter, steps shown in FIG. 3H and the subsequent figures for a first embodiment are carried out to complete a DRAM.

### Third Embodiment

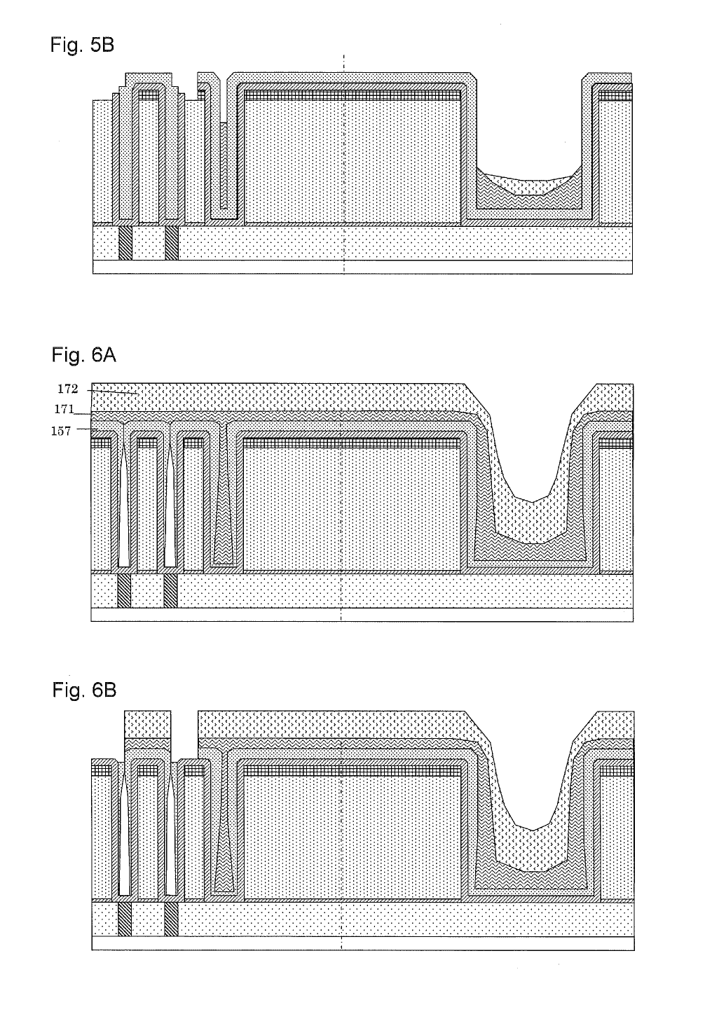

In a third embodiment, a manufacturing method according to a first or second embodiment is partly changed. A method of manufacturing a semiconductor device according to a third embodiment will be described with reference to FIGS. 5A and 5B. FIGS. 5A and 5B are vertical sectional views showing the structure of memory cells during the respective manufacturing steps, which are taken across line LX13a-LX13b in FIG. 10.

### <Step of Forming a Structure Shown in FIG. 5A>

Steps shown in FIGS. 3A to 3E for a first embodiment and a step shown in FIG. 4A for a second embodiment are carried out. Subsequently, exposed capacitor beam insulating film 151 is etched away.

### <Step of Forming a Structure Shown in FIG. 5B>

A step shown in FIG. 3F for a first embodiment is carried out to leave photo resists film 172 and antireflection film 171 in a large capacitor portion. At this time, the memory cell has substantially the same sectional shape as that of the structure shown in FIG. 3G for a first embodiment.

### <Subsequent Steps>

Steps shown in FIG. 3H and the subsequent figures for a first embodiment are carried out to complete a DRAM.

### Fourth Embodiment

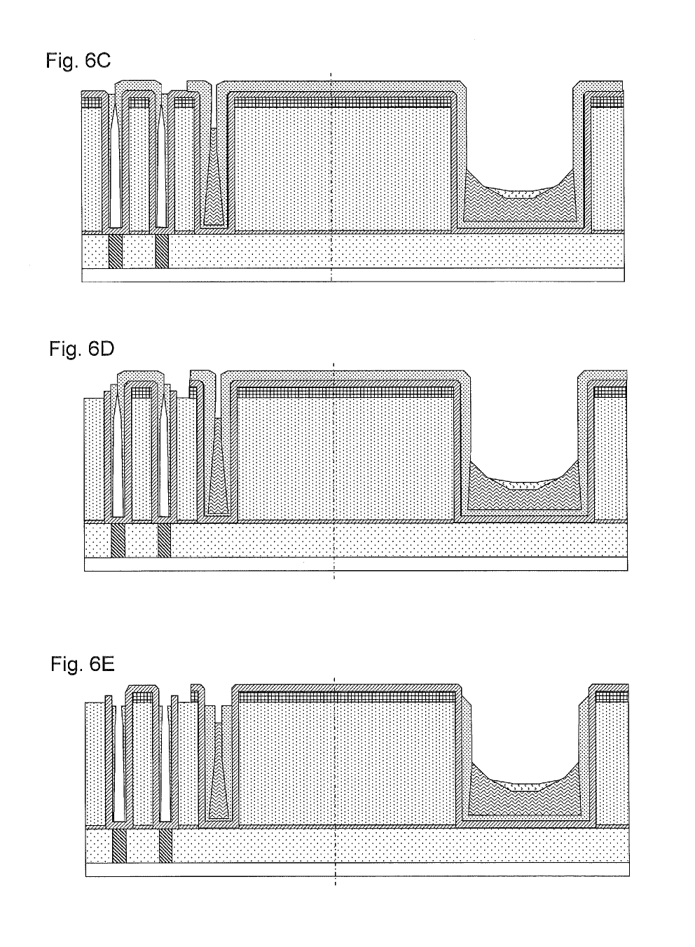

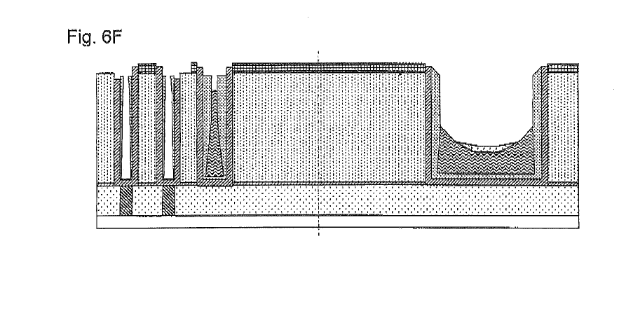

First to third embodiments use a silicon oxide film formed by the CVD method, as a material for the mask insulating film. However, a fourth embodiment discloses a method of forming mask insulating film 157 by a plasma CVD method which requires reduced manufacturing costs and which offers a high throughput. A method of manufacturing a semiconductor device according to a fourth embodiment will be described with reference to FIGS. 6A to 6H. FIGS. 6A to 6H are vertical sectional views showing the structure of memory cells during respective manufacturing steps, which are taken across line LX13a-LX13b in FIG. 10.

### <Step of Forming a Structure Shown in FIG. 6A>

Steps shown in FIGS. 3A to 3E for a first embodiment and a step of forming storage electrode conductive film 155 as shown in FIG. 3C are carried out.

Mask insulating film 157 is deposited using the plasma CVD method. The film thickness of mask insulating film 157 is such that the top of the hole portion is blocked. Mask insulating film 157 is grown so as to have a film thickness ranging from a value equal to the diameter of the hole portion to a value about double the diameter of the hole portion. The plasma CVD method offers low coatability. Hence, the hole portion of the mask insulating film is closed at the top. Furthermore, a void is formed inside the hole. In a fourth embodiment, the hole has an opening width of 100 nm, and mask insulating film 157 is deposited to a thickness of about 100 nm. The top surface of the array portion with memory cell capacitors formed therein is flattened by mask insulating film 157. This facilitates lithography for forming the subsequent capacitor beam insulating film. Antireflection film 171 and photo resist film 172 are deposited as is a case with a first embodiment.

### <Step of Forming a Structure Shown in FIG. 6B>

As is a case with a first embodiment, the lithography technique is used to form a resist pattern required to process and form capacitor beams. The resist pattern covers the capacitor beam formation region in the memory cell and the regions outside guard ring 162. Lithography mark 163 is covered with the resist.

Antireflection film 171 is etched away by dry etching through photo resist film 172 as a mask. Subsequently, mask insulating film 157 is etched away by dry etching.

### <Step of Forming a Structure Shown in FIG. 6C>

As is a case with a first embodiment, photo resist mask film 172 and antireflection film 171 on the capacitor interlayer film are etched away by dry etching to expose mask insulating film 157. At this time, photo resist film 172 or antireflection film 171 are left at the bottom of the hole portion of lithography mark 163, which has the largest opening width.

### <Step of Forming a Structure Shown in FIG. 6D>

As is a case with a first embodiment, storage electrode conductive film 155 and capacitor beam insulating film 151 are etched away by dry etching through mask insulating film 157 as a mask.

### <Step of Forming a Structure Shown in FIG. 6E>

As is a case with a first embodiment, mask insulating film 157 on capacitor interlayer film 150 is removed. Mask insulating film 157 formed at the bottom of lithography mark 163 is left and protected by photo resist film 172 and antireflection film 171.

If mask insulating film 157 offers low coatability in the hole portion of the memory cell capacitor, the top of a void formed in the hole portion of the memory cell capacitor as a result of the above-described etching may be exposed to form an opening. FIG. 6E shows that an opening has been formed. When the opening is formed, the mask insulating film formed at the bottom of the memory cell capacitor hole may be etched to expose the surface of the storage electrode conductive film. However, if mask insulating film 157 offers high coatability, the opening is not formed.

### <Step of Forming a Structure Shown in FIG. 6F>

As is a case with a first embodiment, storage electrode conductive film 155 on capacitor interlayer film 150 is removed to electrically separate storage electrode conductive film 155 in the adjacent memory cell capacitors into pieces for the respective memory cell capacitors. Storage electrode conductive film 155 formed on guard ring 162, which is a large capacitor pattern, and at the bottom of lithography mark 163, which is a large capacitor, is protected by photo resist film 172, antireflection film 171 and the mask insulating film. Thus, storage electrode conductive film 155 formed in these portions remains without being etched.

On the other hand, the memory cell portion is formed as is a case with a first embodiment without a problem provided that storage electrode conductive film 155 is masked by mask insulating film 157. However, it is assumed that an opening may be formed in mask insulating film 157 formed at the top of the hole portion of the memory cell capacitor and that the mask insulating film formed at the bottom of the hole portion may be removed by etching and does not remain, as shown in FIG. 6E. Even if mask insulating film 157 is not formed at the bottom of the capacitor hole, storage electrode conductive film 155 formed at the bottom of the hole can be prevented from being etched by setting an aspect ratio, that is, the height to opening width of the opening measured after formation of storage electrode conductive film 155, to 7 or more, without the need to protect the bottom of the hole using mask insulating film 157 (Japanese Patent Laid-Open No. 2006-140405A and Japanese Patent Laid-Open No. 2003-347430A). If almost none of mask insulating film 157 is deposited at the bottom of the capacitor hole, the aspect ratio of the memory cell capacitor needs to be set to 7 or more.

### <Subsequent Steps>

A DRAM is completed through steps shown in FIG. 3J and subsequent figures for a first embodiment.

Use of a method according to a fourth embodiment allows mask insulating film 157 on storage electrode conductive film 155 to be formed by the plasma CVD method, which requires reduced manufacturing costs and which offers high throughput. This enables a reduction in production costs.

### <<<Fifth Embodiment>>>

In first to fourth embodiments, mask insulating film 157 is formed on storage electrode conductive film 155. Furthermore, differences in level formed by the hole portions of the memory cell capacitors are flattened by the mask insulating film, thus enabling lithography to be facilitated. If mask insulating film 157 is not formed, the following problems are likely to occur: halation resulting from reflection of light from the differences in level formed by the hole portions of the memory cell capacitors and a variation in size caused by a variation in the film thickness of antireflection film 171 or resist film 172.

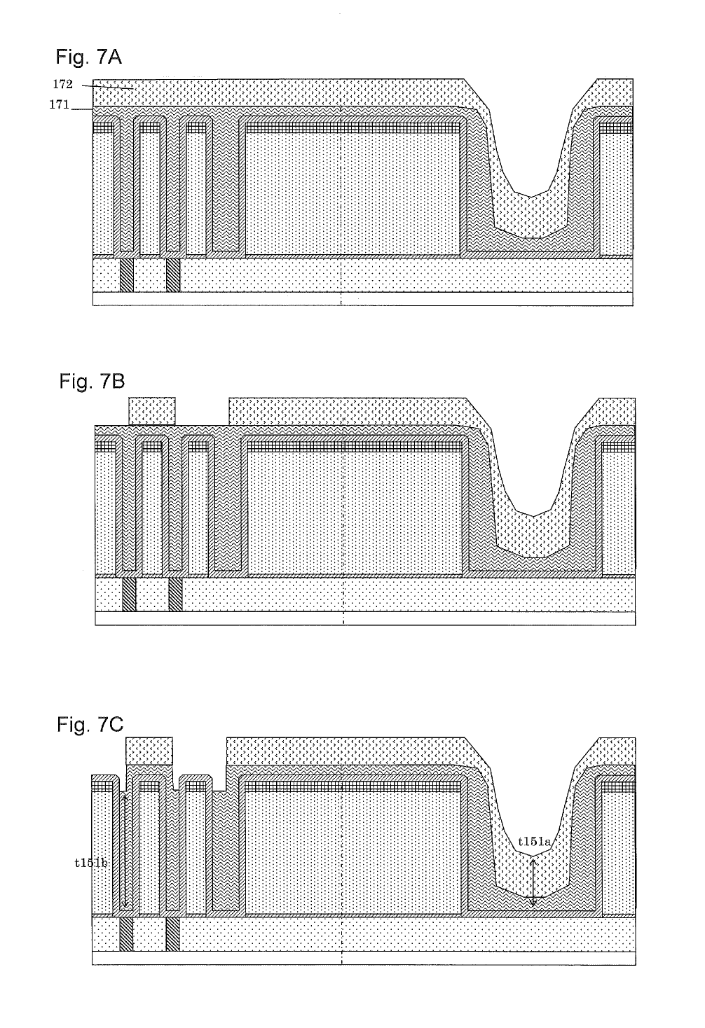

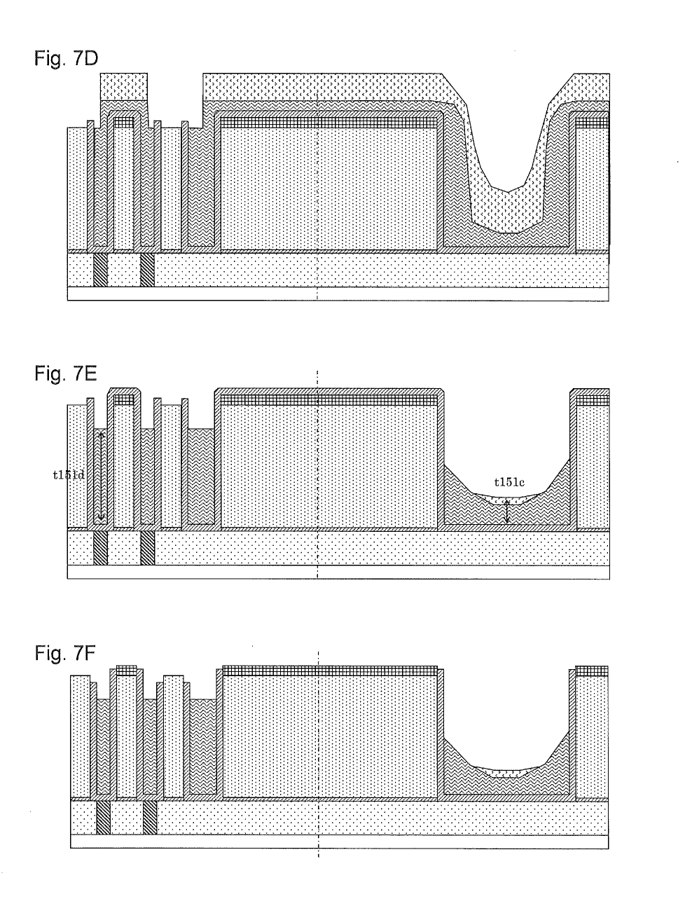

However, if these adverse effects are insignificant because, for example, the width of a pattern of capacitor beams is large, it is possible to use a method of avoiding forming a mask insulating film. This method will be disclosed in a fifth embodiment. A method of manufacturing a semiconductor device according to a fifth embodiment will be described with reference to FIGS. 7A to 7F. FIGS. 7A to 7F are vertical sectional views showing the structure of memory cells during respective manufacturing steps, which are taken across line LX13a-LX13b in FIG. 10.

### <Step of Forming a Structure Shown in FIG. 7A>

Steps shown in FIGS. 3A and 3B for a first embodiment and a step of forming storage electrode conductive film 155 as shown in FIG. 3C are carried out.

Thereafter, as is a case with a first embodiment, antireflection film 171 and photo resist film 172 are applied. For example, antireflection film 171 has a film thickness of 100 nm, and photo resist film 172 has a film thickness of 300 nm. As is a case with a first embodiment, antireflection film 171 and photo resist film 172 are formed such that the film thickness of each of antireflection film 171 and photo resist film 172 is larger in the large capacitor portion, which has the largest opening diameter, than on the capacitor interlayer film. If the adverse effects of the differences in level formed by the hole portions of the memory cell capacitors are nonnegligible, the thickness of antireflection film 171 may need to be increased to prevent the adverse effect of reflection during a subsequent exposure step.

### <Step of Forming a Structure Shown in FIG. 7B>

The lithography technique is used to form a resist pattern required to form capacitor beams. In a fifth embodiment, no mask insulating film is formed, and thus attention needs to be paid to the possible adverse effects of the underlying differences in level formed by the memory cell capacitor holes.

### <Step of Forming a Structure Shown in FIG. 7C>

Antireflection film 171 is etched away by dry etching through photo resist film 172 as a mask. The etching is performed so as to expose the surface of storage electrode conductive film 155. In this step, the overetching amount of etching of antireflection film 171 is set such that distance t151b from the etched top surface of the antireflection film buried in the hole portion of the memory cell capacitors, to the bottom surface of the trench, is equal to or larger than distance t151a from the position of the top surface of the resist film in the hole portion of lithography mark 163, which is a large capacitor pattern, to the bottom surface of the trench.

### <Step of Forming a Structure Shown in FIG. 7D>

Storage electrode conductive film 155 and capacitor beam insulating film 151 are sequentially etched through photo resist film 172 and antireflection film 171 as a mask.

### <Step of Forming a Structure Shown in FIG. 7E>

As is a case with FIG. 3F for a first embodiment, photo resist film 172 and antireflection film 171 are dry-etched to remove photo resist film 172 and antireflection film 171 formed on the capacitor interlayer film. Thus, storage electrode conductive film 155 on capacitor interlayer film 150 is exposed. Furthermore, remaining portions t151c and t151d of photo resist film 172 and antireflection film 171 which portions each have a thickness of about 50 nm or more are left at the bottom of each of the hole portions of lithography mark 163 and the memory cell capacitor. This avoids exposing the surface of storage electrode conductive film 155 formed at the bottom during the etching in a subsequent step. The thicknesses of the remaining films are controlled based on the overetching amount of dry etching and initial film thicknesses t151a and t151b. However, in the hole portion of the memory cell capacitor, as described in a fourth embodiment, setting the aspect ratio of the opening to 7 or more allows prevention of a possible failure to etch storage electrode conductive film 155 formed at the bottom without the need to take the remaining portion of the antireflection film on storage electrode conductive film 155 into account.

### <Step of Forming a Structure Shown in FIG. 7F>

Storage electrode conductive film 155 on capacitor interlayer film 150 is removed by dry etching through antireflection film 171 and photo resist film 172 as a mask, both of which have been stored in the capacitor portion. Thus, the adjacent memory cell capacitors are electrically separated from each other.

### <Subsequent Steps>

A DRAM is completed through steps shown in FIG. 3J and subsequent figures for a first embodiment.

Use of a fifth embodiment eliminates the need for a step of forming and etching mask insulating film 157, thus enabling a reduction in production costs. A fifth embodiment can be implemented under both the following conditions: the capacitor beam pattern can be formed by lithography, and in the etching of antireflection film 171, the remaining portion of antireflection film 171 can be left in the hole portion of the memory cell capacitor.

### Sixth Embodiment

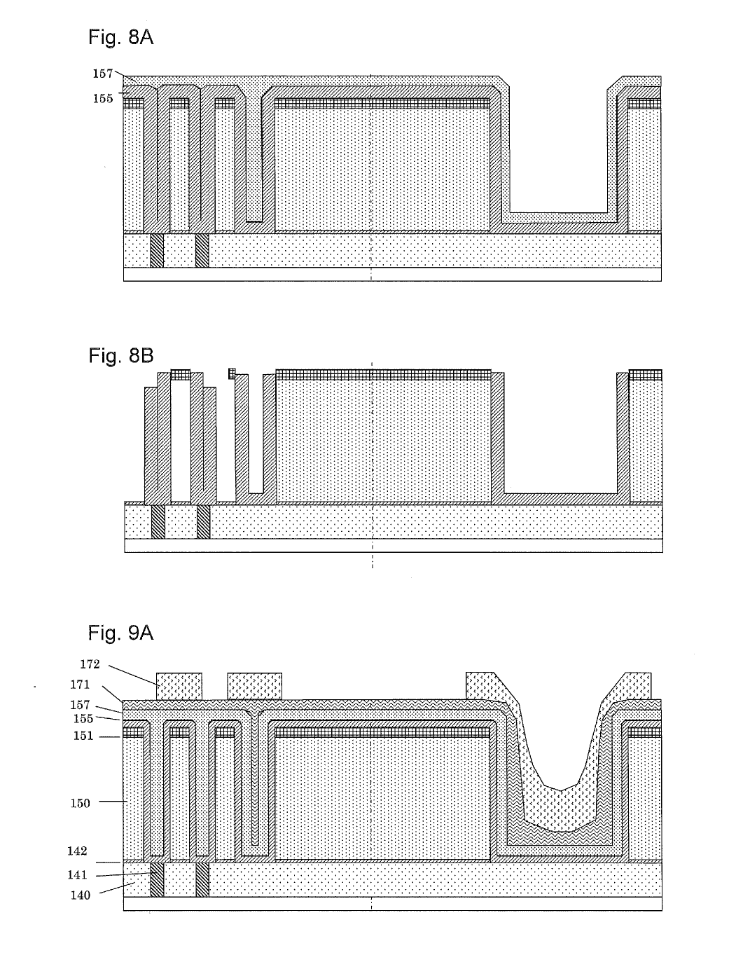

In first to fifth embodiments, each of the storage electrodes in the memory cell portion is shaped like a cylinder with a void in the inner wall. However, a sixth embodiment discloses a method of forming a capacitor that uses a cylindrical electrode with storage electrode conductive film 155 buried in an inner wall portion. A method of manufacturing a semiconductor device according to a sixth embodiment will be described with reference to FIGS. 8A and 8B. FIGS. 8A and 8B are vertical sectional views showing the structure of memory cells during respective manufacturing steps, which are taken across line LX13a-LX13b in FIG. 10.

### <Step of Forming a Structure Shown in FIG. 8A>

Steps shown in FIGS. 3A and 3B for a first embodiment and a step of forming storage electrode conductive film 155 as shown in FIG. 3C are carried out. However, in the growth of storage electrode conductive film 155, for example, a TiN film is grown by 60 nm so as to be buried in the memory cell opening. Thereafter, mask insulating film 157 is formed as is a case with a first embodiment.

### <Step of Forming a Structure Shown in FIG. 8B>

Steps as those shown in FIGS. 3D to 3K for a first embodiment are carried out.

### <Subsequent Steps>

A DRAM is completed through steps shown in FIG. 3L and subsequent figures for a first embodiment.

A further reduction in memory cell size reduces the size of a void portion formed in the inner wall. The void portion thus does not substantially contribute as a capacitance. In other cases, the storage electrode conductive film is buried in to prevent a void from being formed. In this case, a structure with only the outer wall accessible is used as in a sixth embodiment. For example, if the opening width of the memory cell capacitor hole is reduced down to 50 nm, when a TiN film is formed which has the same film thickness as that in a first embodiment, that is, 30 nm, the conductive film is buried in the inner wall of the memory cell capacitor hole. As a result, a cylindrical capacitor with only the outer wall accessible is formed.

### Seventh Embodiment

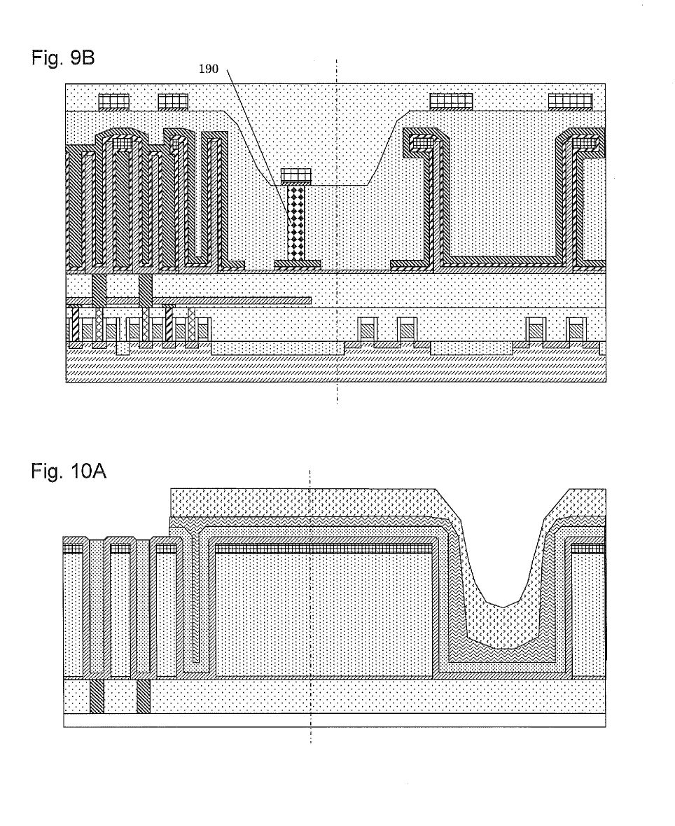

In first to sixth embodiments, in an etching step of exposing the outer wall of storage electrode conductive film 155, capacitor interlayer film 150 is removed only from the memory cell portion by means of wet etching. In a seventh embodiment, the regions outside the guard ring with respect to the memory cell are also etched. A method of manufacturing a semiconductor device according to a seventh embodiment will be described with reference to FIGS. 9A and 9B. FIG. 9A is a vertical sectional view showing a structure of memory cells during a manufacturing step, which is taken across line LX13a-LX13b in FIG. 1C. FIG. 9B is a vertical sectional view showing a structure of a completed memory cell, which corresponds to FIG. 1A.

### <Step of Forming a Structure Shown in FIG. 9A>

Steps shown in FIGS. 3A to 3E for a first embodiment are carried out. However, in a seventh embodiment, a pattern of supports in memory cells and a pattern covering guard ring 162 and lithography mark 163 are formed. No mask pattern is formed between the intermediate region between the above-described patterns.

### <Step of Forming a Structure Shown in FIG. 9B>

A DRAM is completed through steps shown in FIG. 3F and subsequent figures for a first embodiment.

A guard ring is formed so as to surround the periphery of the memory cell array. In this case, the guard ring is left and located around the memory cell array in order to prevent the corners of the memory cell capacitors from being exposed during a step of flattening the interlayer film on the plate electrode. The guard ring may be omitted provided that the possible exposure of the corners of the memory cell capacitors is prevented by any other means.

In a step of subjecting the capacitor interlayer film to wet etching, the height, from the substrate, of the interlayer film formed in the peripheral portion can be reduced by also etching the peripheral portion. This advantageously facilitates etching for formation of through-holes 190 and the electric connection of the through-holes. In this case, differences in level are formed between the memory cell portion and the peripheral portion, making formation of wires difficult. Hence, the etching of the peripheral portion can be used when processing of a wiring pattern has margin.

### Eighth Embodiment

In first to seventh embodiments, a capacitor beam is formed to support a storage electrode in a memory cell. However, if the strength of the capacitor has no problem, a structure with no capacitor beam formed can be used. An eighth embodiment discloses a method of manufacturing such a structure. In a method, in a lithography step of forming a mask pattern of support beams, a pattern is used which allows openings to be formed in a memory cell region with no capacitor beam formed. A method of manufacturing a semiconductor device according to an eighth embodiment will be described with reference to FIGS. 10A to 10C. FIGS. 10A to 10C are vertical sectional views showing a structure of memory cells during respective manufacturing steps, which are taken across line LX13a-LX13b in FIG. 1C.

### <Step of Forming a Structure Shown in FIG. 10A>

Steps shown in FIGS. 3A to 3E for a first embodiment are carried out. However, the pattern of capacitor beams in the memory cells is not formed.

### <Step of Forming a Structure Shown in FIG. 10B>

As is a case with a step shown in FIG. 3F for a first embodiment, photo resist film 172 and antireflection film 171 are etched by dry etching so as to remove photo resist film 172 and antireflection film 171 formed on capacitor interlayer film 150. In this case, photo resist film 172 and antireflection film 171 are left in lithography mark 163. Thereafter, as is a case with steps shown in FIGS. 3G to 3I for a first embodiment, mask insulating film 157, storage electrode conductive film 155, capacitor beam insulating film 151, and mask insulating film 157 all of which are formed on capacitor interlayer film 150 are etched.

### <Step of Forming a Structure Shown in FIG. 10C>

As is a case with steps shown in FIGS. 3J to 3K for a first embodiment, the outer wall of storage electrode conductive film 155 in memory cell capacitor 161 is exposed.

Lithography with about F-number needs to be used to form capacitor beams. However, if no beam is formed, this micro lithography step is unnecessary, allowing production steps to be inexpensively achieved.

### Other Embodiments

In first to eighth embodiments, an exemplary embodiment is applied to cylinder capacitors in a DRAM. However, an exemplary embodiment is not limited to this application. An exemplary embodiment is applicable to any semiconductor device having a structure similar to that of a cylinder capacitor and including an electrode with different opening widths.

In first to eighth embodiments, the antireflection film and the photo resist film are used as a bottom protection film for the large capacitor pattern. However, a mask insulating film may be buried in the large capacitor pattern. In this case, besides the non-doped silicon oxide film, a BPSG film, an SOG film, or the like may be applied to form the mask insulating film. First to eighth embodiments use a silicon oxide film as a cylinder interlayer film. However, an exemplary embodiment is not limited to this configuration. Any insulating film such as a BPSG film or an SOG film may be used.

First to eighth embodiments use a silicon nitride film as a capacitor beam insulating film. However, any material may be used for which hydrofluoric acid exhibits a high etching selectivity when the cylinder interlayer film is etched using the hydrofluoric acid. A tantalum oxide film, alumina, or the like is applicable. Furthermore, in a first to eighth embodiments, a silicon nitride film is used as a capacitor beam insulating film, a silicon oxide film is used as a cylinder interlayer film, and a TiN film is used as a lower electrode. Furthermore, the cylinder oxide film is etched using hydrofluoric acid. However, an exemplary embodiment is not limited to these materials and etching methods. Any materials and etching conditions may be used which exhibit a high etching selectivity for the capacitor beam insulating film and the lower electrode material over the cylinder interlayer film.

1-3. (canceled)

4. A semiconductor device comprising:
a semiconductor substrate having a principal surface;
a first conductor formed over the semiconductor substrate, the first conductor including first side wall portions in opposition to each other at a separation of a first distance in a horizontal direction and a first bottom portion continuously formed to connect between the first side wall portions;
a second conductor formed over the semiconductor substrate, the second conductor including second side wall portions in opposition to each other at a separation of a second distance in a horizontal direction and a second bottom portion continuously formed to connect between the second side wall portions, the second distance being larger than the first distance;
a third conductor formed at least over outer surfaces of both sides of the first side wall portions of the first conductor through a dielectric layer; and
a fourth conductor formed at least over outer surfaces of both sides of the second side wall portions of the second conductor through a dielectric layer,
wherein one of top ends of the first side wall portions is located at a position lower than the other of the top ends of the first side wall portions.

5. The semiconductor device according to claim 4, wherein the third conductor and the fourth conductor are separated from each other.

6. The semiconductor device according to claim 4, further comprising a first cap film being in contact with the first conductor at a contact portion of the outer surfaces of the first side wall portions.

7. The semiconductor device according to claim 4, further comprising a second cap film being in contact with the second conductor at a contact portion of the outer surfaces of the second side wall portions.

8. The semiconductor device according to claim 6, wherein the top end of the first side wall portions of the first conductor in the vicinity of the contact portion is located at a position lower than a top surface of the first cap film.

9. The semiconductor device according to claim 7, wherein a top end of the second side wall portions of the second conductor in the vicinity of the contact portion is located at a position lower than a top surface of the second cap film.

10. The semiconductor device according to claim 7, wherein the fourth conductor has a horizontally extending end portion.

11. The semiconductor device according to claim 10, wherein the horizontally extending end portion of the fourth conductor is located at a position lower than a bottom surface of the second cap film and at a position higher than a bottom end of the second bottom portion of the second conductor.

12. A semiconductor device comprising:
a semiconductor substrate having a principal surface;
a first conductor formed over the semiconductor substrate, the first conductor including first side wall portions in opposition to each other and a first bottom portion continuously formed to connect between the first side wall portions, and top ends of the first side wall portions being at a separation of a first distance;
a second conductor formed over the semiconductor substrate, the second conductor including second side wall portions in opposition to each other and a second bottom portion continuously formed to connect between the second side wall portions, top ends of the second side wall portions being at a separation of a second distance, and the second distance being larger than the first distance;
a third conductor formed at least over outer surfaces of both sides of the first side wall portions of the first conductor through a dielectric layer; and
a fourth conductor formed at least over outer surfaces of both sides of the second side wall portions of the second conductor through a dielectric layer,
wherein one of the top ends of the first side wall portions is located at a position lower than the other of the top ends of the first side wall portions.

13. The semiconductor device according to claim 12, wherein the third conductor and the fourth conductor are separated from each other.

14. The semiconductor device according to claim 12, further comprising a first cap film being in contact with the first conductor at a contact portion of the outer surfaces of the first side wall portions.

15. The semiconductor device according to claim 12, further comprising a second cap film being in contact with the second conductor at a contact portion of the outer surfaces of the second side wall portions.

16. The semiconductor device according to claim 14, wherein the top end of the first side wall portions of the first conductor in the vicinity of the contact portion is located at a position lower than a top surface of the first cap film.

17. The semiconductor device according to claim 15, wherein the top end of the second side wall portions of the second conductor in the vicinity of the contact portion is located at a position lower than a top surface of the second cap film.

18. The semiconductor device according to claim 15, wherein the fourth conductor has a horizontally extending end portion.

19. The semiconductor device according to claim 18, wherein the horizontally extending end portion of the fourth conductor is located at a position lower than a bottom surface of the second cap film and at a position higher than a bottom end of the second bottom portion of the second conductor.

20. A semiconductor device comprising:
a semiconductor substrate having a principal surface;
a first conductor formed over the semiconductor substrate, the first conductor including first side wall portions in opposition to each other and a first bottom portion continuously formed to connect between the first side wall portions, and top ends of the first side wall portions being at a separation of a first distance;
a second conductor formed over the semiconductor substrate, the second conductor including second side wall portions in opposition to each other and a second bottom portion continuously formed to connect between the second side wall portions, top ends of the second side wall portions being at a separation of a second distance, and the second distance being larger than the first distance;
a third conductor formed at least over outer surfaces of both sides of the first side wall portions of the first conductor through a dielectric layer;
a fourth conductor formed at least over outer surfaces of both sides of the second side wall portions of the second conductor through a dielectric layer; and
a cap film having an end portion that is horizontally extended in a shape of an eaves and is in contact with the second conductor at a contact portion of at least one of the outer surfaces of the second side wall portions,
wherein one of the top ends of the first side wall portions is located at a position lower than the other of the top ends of the first side wall portions.

21. The semiconductor device according to claim 20, wherein the fourth conductor covers a top surface, a bottom surface and an 5 end surface of the end portion of the cap film through a dielectric film.

22. The semiconductor device according to claim 21, wherein the fourth conductor has a horizontally extending end portion that is located at a position lower than the bottom surface of the end portion of the cap film and at a position higher than a bottom end of the second bottom portion of the second conductor.

23. The semiconductor device according to claim 22, wherein the third conductor and the fourth conductor are separated from each other.
